(19) United States
(12) Patent Application Publication
(10) Pub. No.: US 2024/0387600 A1
(43) Pub. Date: Nov. 21, 2024

(54) OPTOELECTRONIC DEVICE INCLUDING NEAR INFRARED PHOTODIODES AND NEAR INFRARED LIGHT EMITTING DIODES

(71) Applicant: Taiwan Semiconductor Manfacturing Company, Ltd., Hsinchu (TW)

(72) Inventors: Chun-Hao LIN, Tainan City (TW); Yun-Wei CHENG, Taipei City (TW); Kuo-Cheng LEE, Tainan City (TW)

(21) Appl. No.: 18/319,229

(22) Filed: May 17, 2023

(51) Int. Cl. H01L 27/146; H01L 25/16

(52) U.S. Cl. CPC H01L 27/14649; H01L 25/167; H01L 27/14621; H01L 27/14645; H01L 27/14685

(57) ABSTRACT

Some implementations described herein include an optoelectronic device for a low-lighting application and techniques to form the optoelectronic device. The optoelectronic device includes near infrared light emitting diodes, near infrared photodiodes, and visible light photodiodes combined in a single substrate. The near infrared light emitting diodes and the near infrared photodiodes are formed using a selectively grown epitaxial material. The selectively grown epitaxial material (e.g., silicon germanium, gallium arsenide, or another type III/V material) improves a quantum efficiency performance of the near infrared photodiode relative to another photodiode that may be formed through doping a silicon material.

### BACKGROUND

Complementary metal oxide semiconductor (CMOS) image sensor (CIS) devices utilize light-sensitive CMOS circuitry to convert light energy into electrical energy. The light-sensitive CMOS circuitry may include a photodiode formed in a silicon substrate. As the photodiode is exposed to light, an electrical charge is induced in the photodiode (referred to as a photocurrent). The photodiode may be coupled to a switching transistor, which is used to sample the charge of the photodiode. Colors may be determined by placing filters over the light-sensitive CMOS circuitry.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of a portion of an example optoelectronic device described herein.

FIG. 3 is a diagram of an example optoelectronic device described herein.

FIGS. 4A-4N are diagrams of an example implementation for forming an optoelectronic device including near infrared photodiodes and near infrared light emitting diodes.

FIG. 5 is a diagram of an example implementation described herein.

FIG. 6 is a diagram of example components of one or more devices of FIG. 1 described herein.

FIG. 7 is a flowchart of an example process associated with forming an optoelectronic device including near infrared photodiodes and near infrared light emitting diodes.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, an image detection system in a low-lighting environment may include a combination of discrete optoelectronic devices. For example, the image detection system may include discrete near infrared (NIR) light emitting diode (LED) devices for projecting NIR light waves onto a target (e.g., a target for a reflected image), discrete NIR pixel sensor devices for detecting NIR light waves reflected from the target, and discrete visible light (VIS) pixel sensor devices for detecting visible light waves reflected from the target. In addition to drawbacks related to the discrete devices consuming space within the system, silicon-based photodiodes of the NIR pixel sensor devices may have a low quantum efficiency (QE) performance.

An optoelectronic device may include structures using an epitaxially grown type III or type V material (e.g., a type III or type V periodic element). Type III and type V materials are considered as “wide-bandgap materials,” which have higher energy gaps compared to traditional semiconductors materials. This property enables type III and type V materials to absorb photons with higher energies, including those in the infrared region of the spectrum and, as a result, can significantly enhance a quantum efficiency of a photodiode. Further, type III and type V materials have a lower density of defects, which reduces the level of noise and increases the signal-to-noise ratio of the photodiode. Using type III or type V materials in the photodiode can lead to better detection of light, especially for applications that require high sensitivity in low light conditions. The improved quantum efficiency of these photodiodes can be beneficial in areas such as medical imaging, remote sensing, and communication technologies, where reliable and precise detection of light is essential.

Some implementations described herein include an optoelectronic device for a low-lighting application and techniques to form the optoelectronic device. The optoelectronic device includes NIR LEDs, NIR photodiodes, and VIS photodiodes combined in a single substrate. The NIR LEDs and NIR photodiodes are formed using a selectively grown epitaxial material. The selectively grown epitaxial material (e.g., silicon germanium (SiGe), gallium arsenide (GaAs), or another type III/V material) improves a QE performance of the NIR photodiode relative to another photodiode that is formed through doping a silicon material.

By combining the NIR LEDs, the NIR photodiodes, and the VIS photodiodes on the single substrate, a complexity and/or number of manufacturing operations to form the image detection system is lesser relative to the complexity and/or number of manufacturing operations to form another image detection system using discrete NIR LED devices, NIR photodiode devices, and VIS photodiode devices.

In this way, a performance (e.g., a QE) of an NIR pixel sensor device including the NIR photodiode is improved relative to another NIR pixel sensor device including a doped, organic photodiode. Improving the performance of the NIR pixel sensor device increases a manufacturing yield, of the NIR pixel sensor device, to a particular performance threshold. Additionally, combining the NIR LEDs, the NIR photodiodes, and the VIS photodiodes on the single substrate consumes less overall device space (e.g., silicon) and/or image detection system space. By increasing the manufacturing yield and consuming less device space and/or image detection system space, an amount of resources required to support a market that consumes a volume of the image detection system including the NIR LEDs, the NIR photodiodes, and the VIS photodiodes (e.g. semiconductor manufacturing tools, labor, raw materials, and/or computing resources) is reduced.

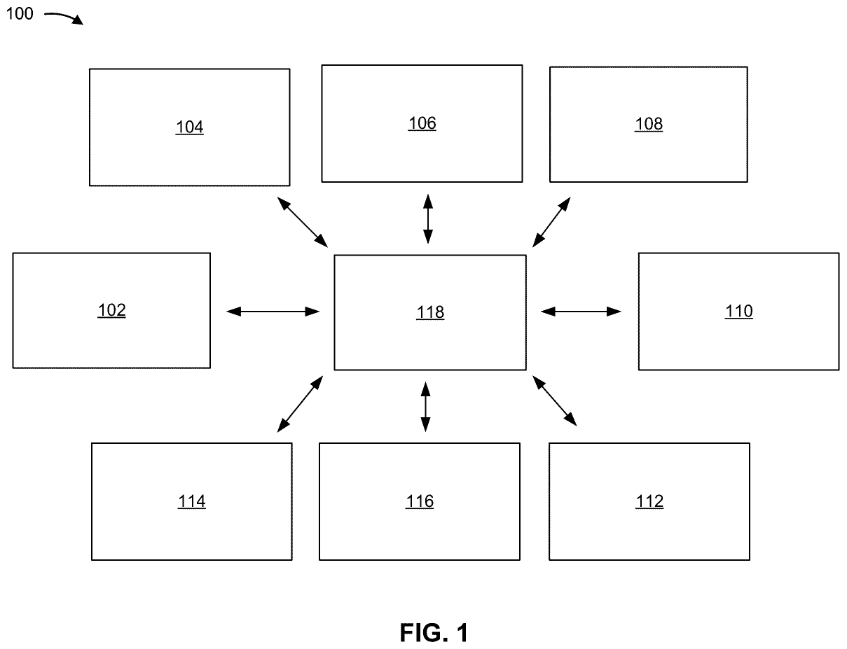

FIG. 1 is a diagram of an example environment 100 in which systems and/or methods described herein may be implemented. As shown in FIG. 1, environment 100 may include a plurality of semiconductor processing tools 102-116 and a wafer/die transport tool 118. The plurality of semiconductor processing tools 102-116 may include a deposition tool 102, an exposure tool 104, a developer tool 106, an etch tool 108, a planarization tool 110, a plating tool 112, an ion implantation tool 114, a bonding/debonding tool 116, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is capable of implanting ions into a substrate. The ion implantation tool 114 may generate ions in an arc chamber from a source material such as a gas or a solid. The source material may be provided into the arc chamber, and an arc voltage is discharged between a cathode and an electrode to produce a plasma containing ions of the source material. One or more extraction electrodes may be used to extract the ions from the plasma in the arc chamber and accelerate the ions to form an ion beam. The ion beam may be directed toward the substrate such that the ions are implanted below the surface of the substrate.

The bonding/debonding tool 116 is a semiconductor processing tool that is capable of joining two or more wafers (or two or more semiconductor substrates, or two or more semiconductor devices) together. For example, the bonding/debonding tool 116 may include a eutectic bonding tool that is capable of forming eutectic bond between two or more wafers together. In these examples, the bonding/debonding tool 116 may heat the two or more wafers to form a eutectic system between the materials of the two or more wafers. As another example, the bonding/debonding tool 116 may include a hybrid bonding tool, a direct bonding tool, and/or another type of bonding tool. In some implementations, the bonding/debonding tool 116 may heat the two or more wafers to separate the two or more wafers.

The wafer/die transport tool 118 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 118 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

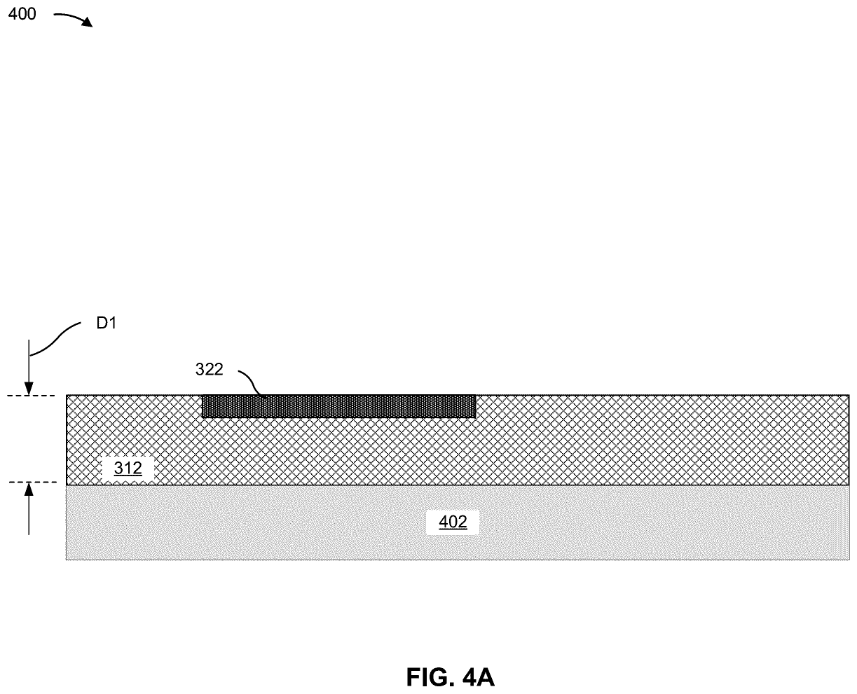

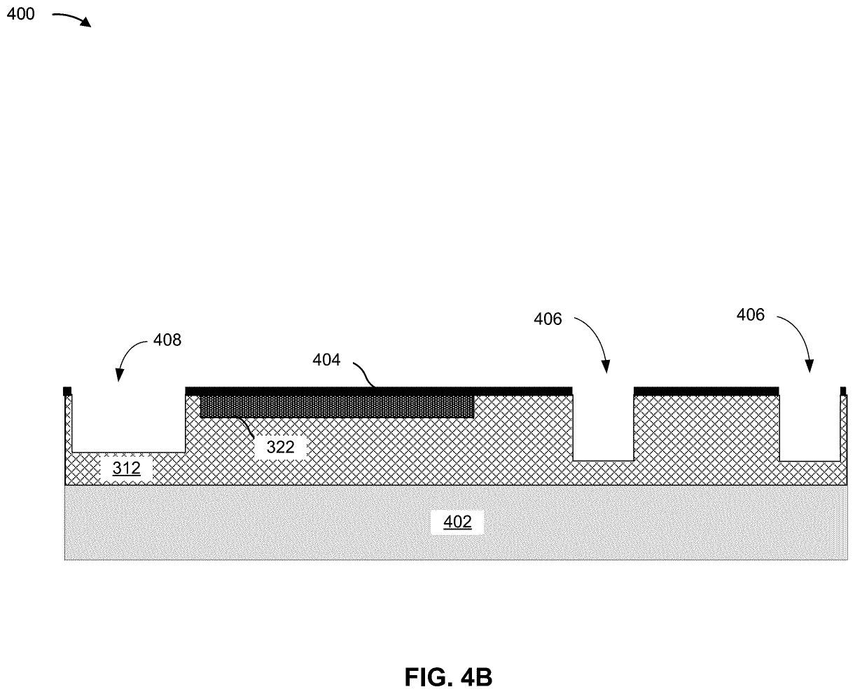

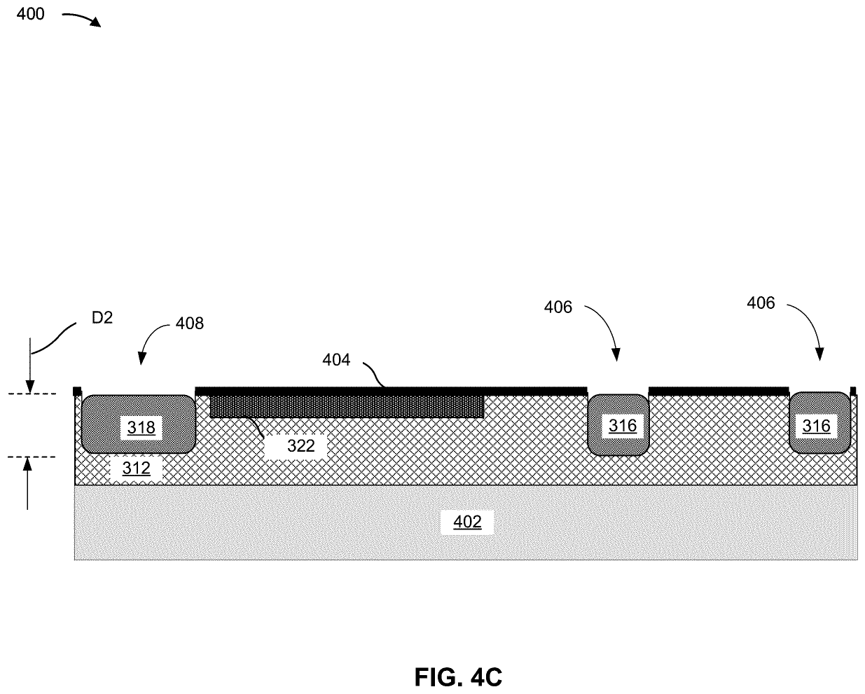

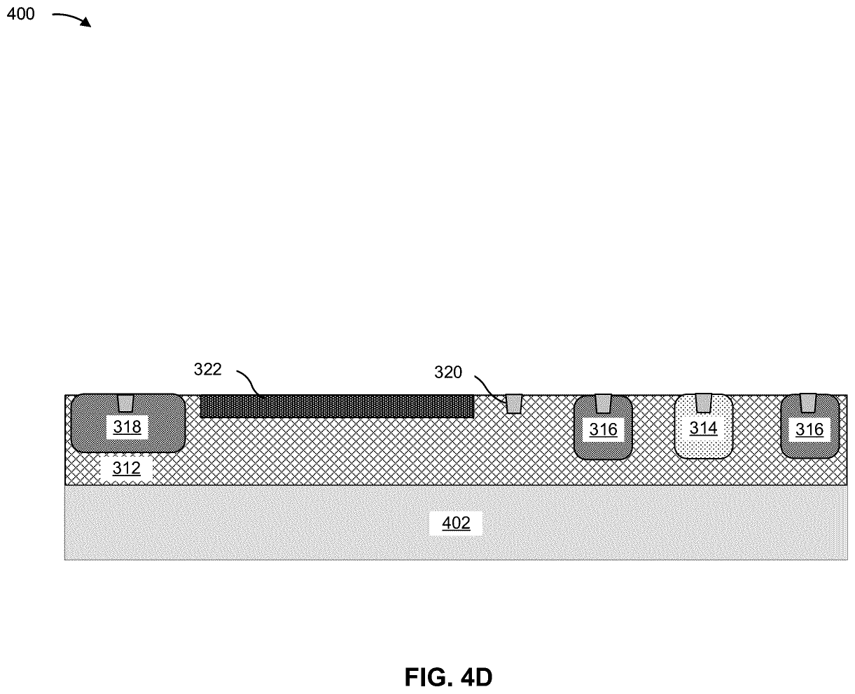

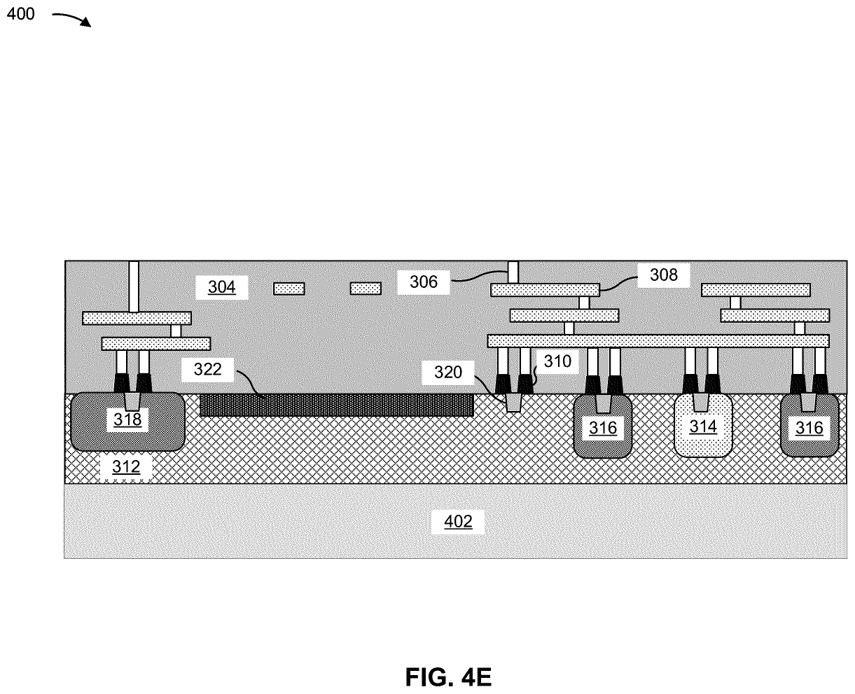

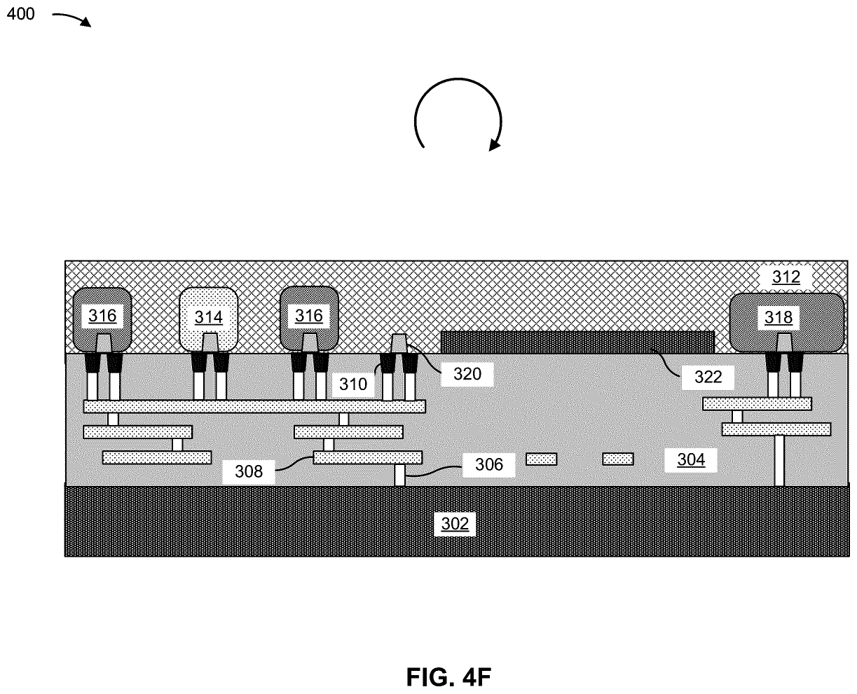

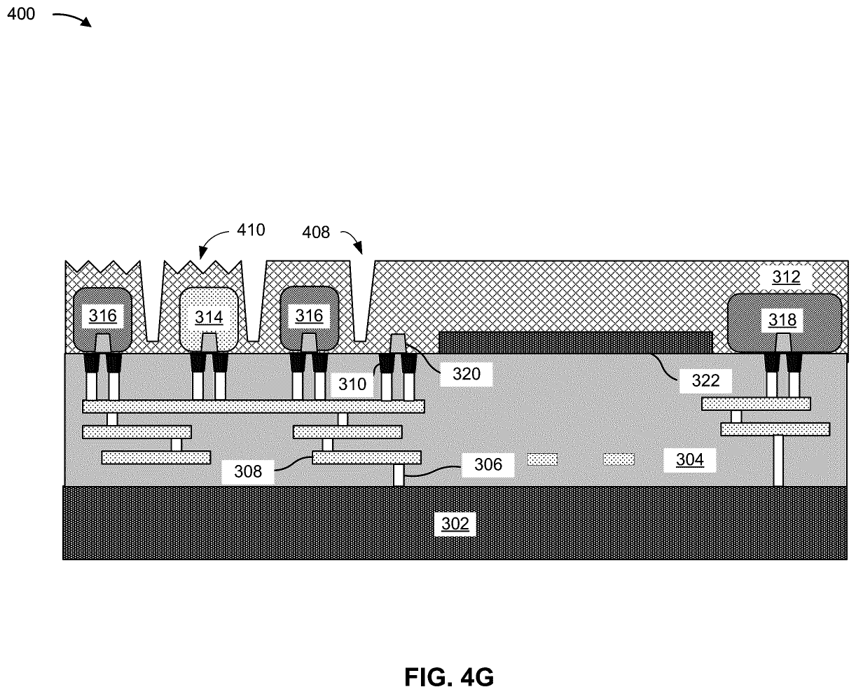

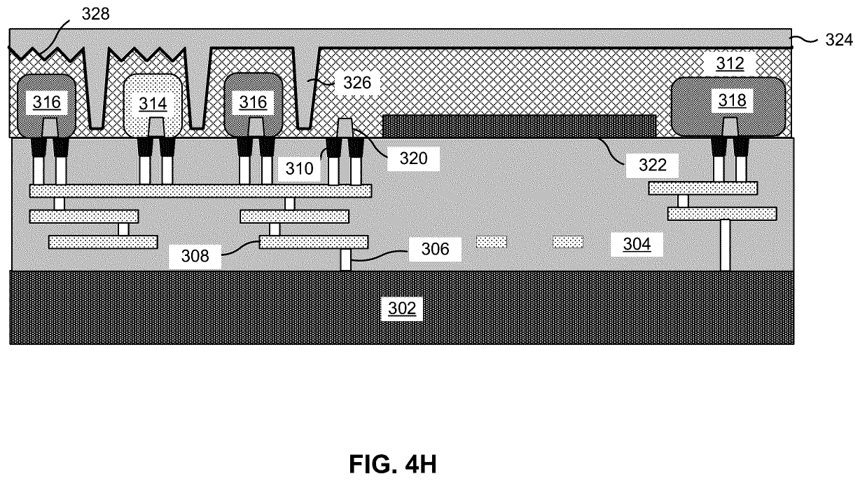

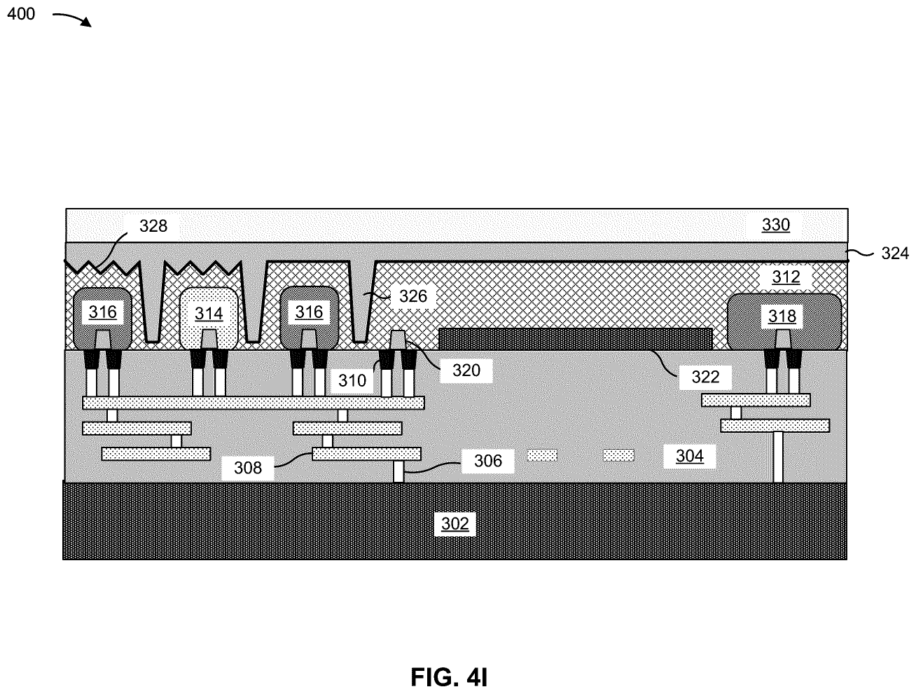

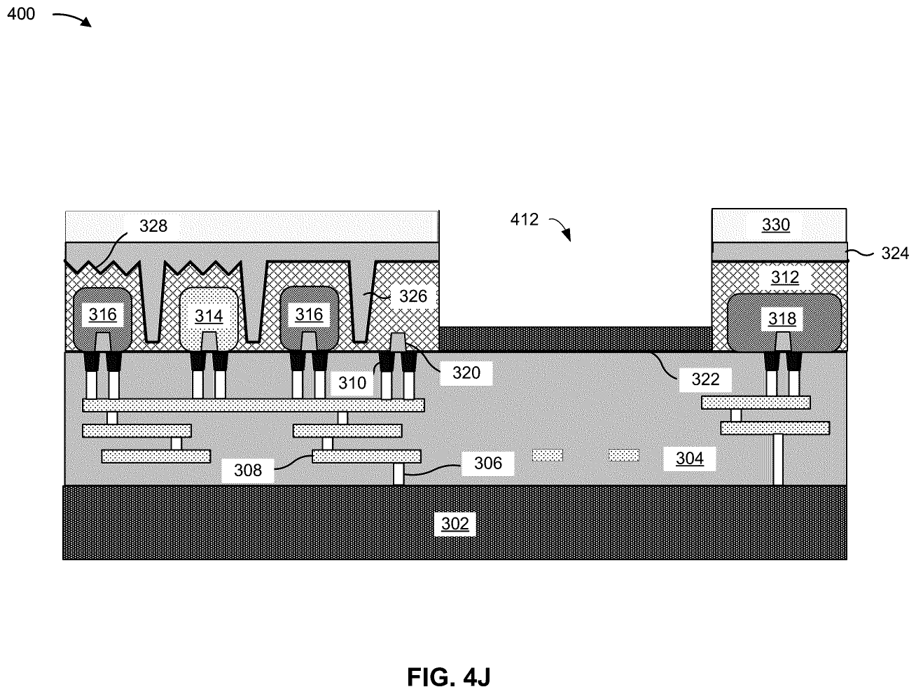

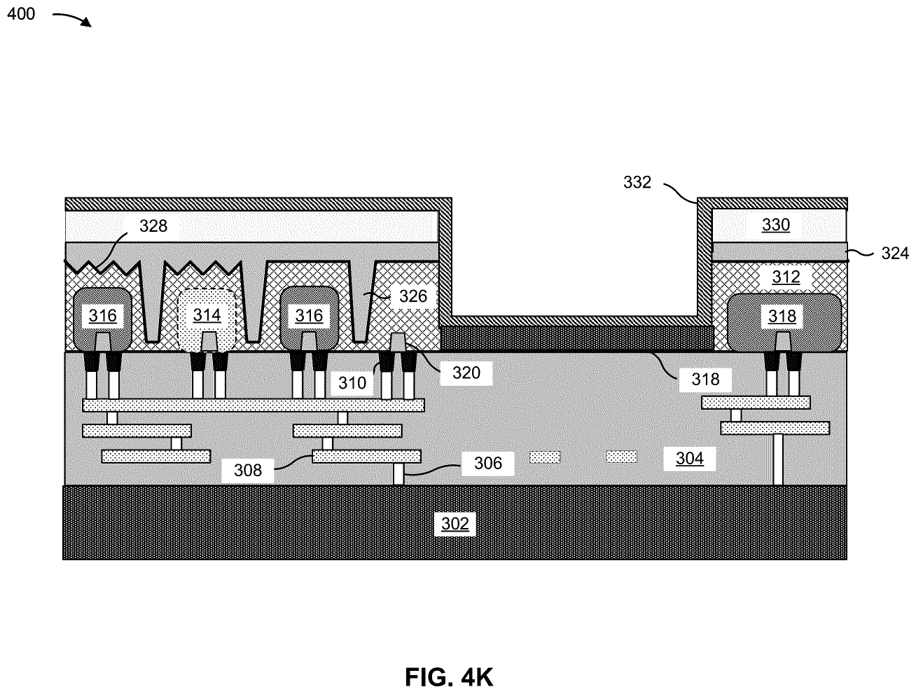

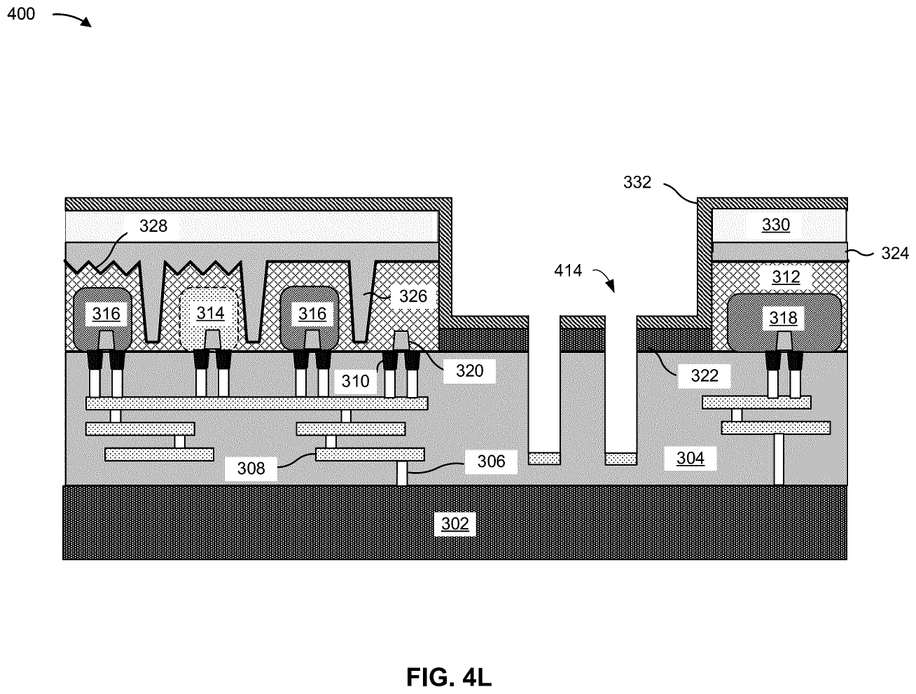

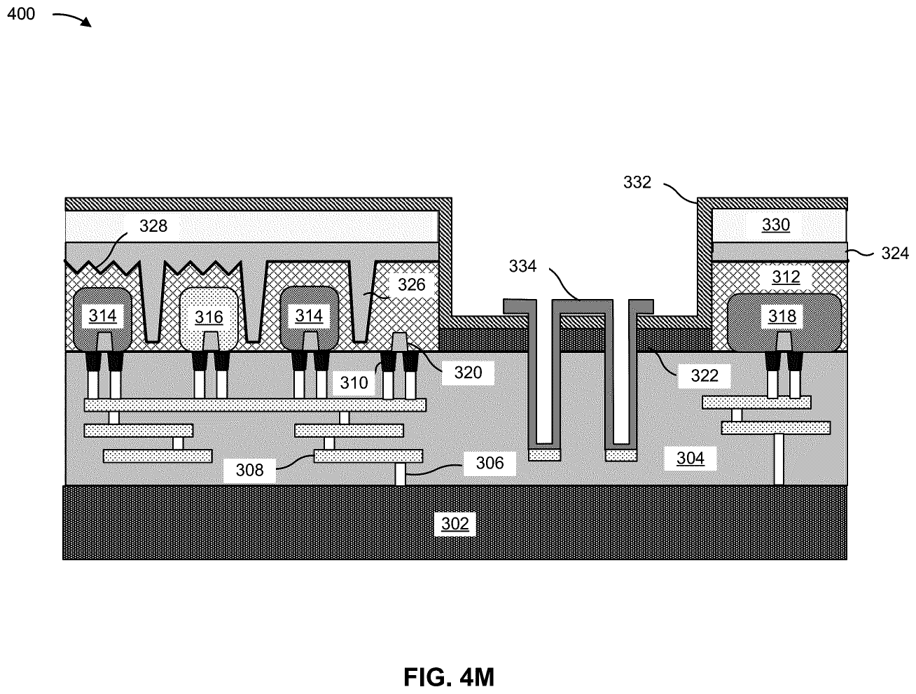

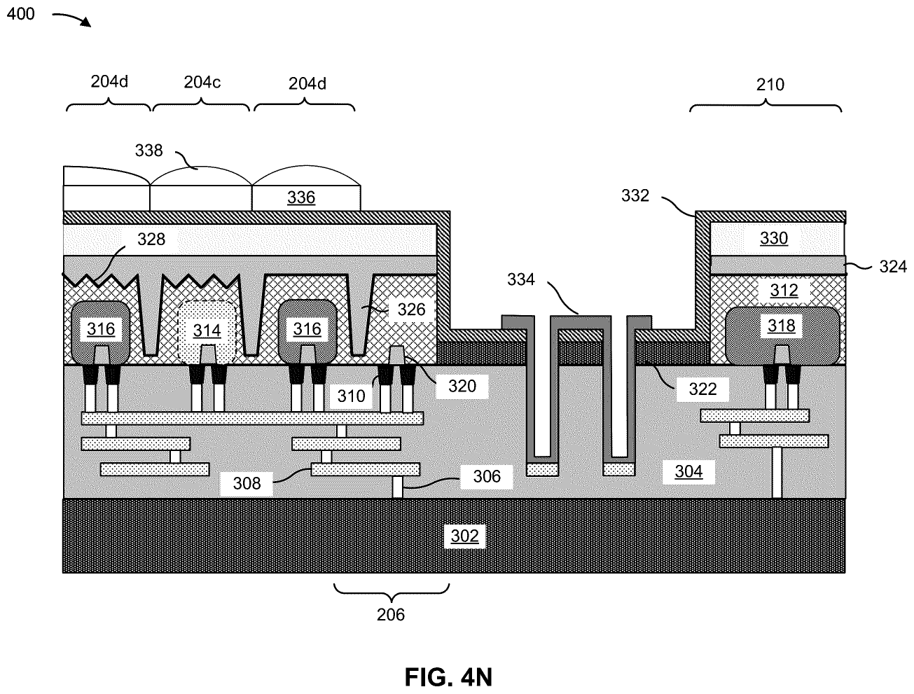

One or more of the semiconductor processing tools 102-116 and/or the wafer/die transport tool 118 may perform a series of one or more semiconductor processing operations described herein. In some implementations, and as an example, the series of one or more semiconductor processing operations includes forming a layer of a semiconductor material on a dielectric region of a semiconductor device. The series of one or more semiconductor processing operations includes forming a first cavity in the layer of the semiconductor material. The series of one or more semiconductor processing operations includes forming a second cavity in the layer of the semiconductor material adjacent to the first cavity. The series of one or more semiconductor processing operations includes forming a near infrared light emitting diode in the first cavity by selectively growing a first epitaxial material in the first cavity. The series of one or more semiconductor processing operations includes forming a near infrared photodiode in the second cavity by selectively growing a second epitaxial material in the second cavity. In some implementations, one or more of the semiconductor processing operations performed by the semiconductor processing tools 102-116 and/or the wafer/die transport tool 118 may correspond to one or more semiconductor processing operations described in connection with FIGS. 4A-4N and elsewhere herein, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

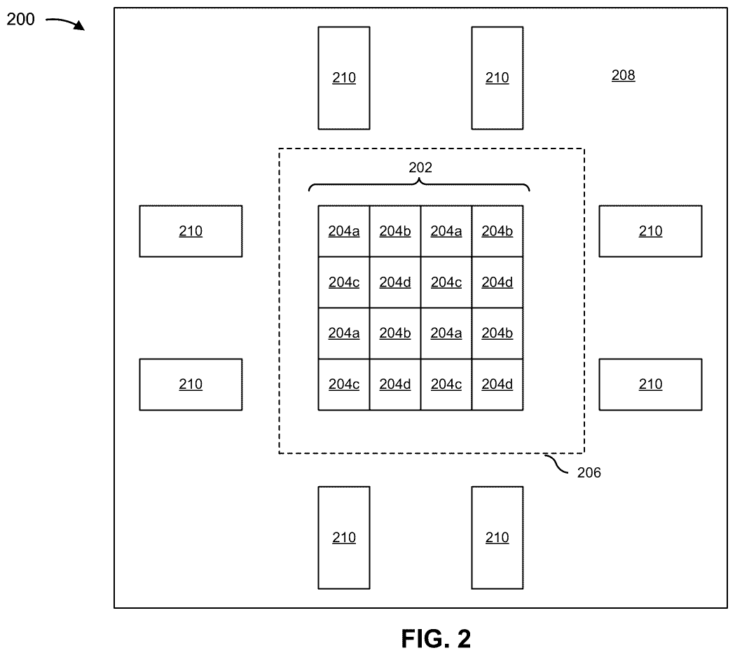

FIG. 2 is a diagram of a portion of an example optoelectronic device 200 described herein. The optoelectronic device 200 may be configured to be deployed in various implementations, such as digital cameras, video recorders, night-vision cameras, automotive sensors and cameras, and/or other types of low-light implementations.

As shown in the top-down view of FIG. 2, the optoelectronic device 200 includes a pixel sensor array 202. As shown in FIG. 2, the pixel sensor array 202 may include pixel sensors 204a-204d. As further shown in FIG. 2, the pixel sensors 204a-204d are arranged in a grid. In some implementations, the pixel sensors 204a-204d are square-shaped (as shown in the example in FIG. 2). In some implementations, the pixel sensors 204a-204d include other shapes such as circle shapes, octagon shapes, diamond shapes, and/or other shapes.

The pixel sensor array 202 may include a filter array that causes the pixels sensors 204a-204d to sense and/or accumulate incident light (e.g., light directed toward the pixel sensor array 202) of particular wavelengths. For example, the pixel sensor 204a may include a color filter that limits the pixel sensor 204a to absorbing and accumulating photons of incident light corresponding to blue visible light (e.g., electromagnetic waves having a wavelength in a range of approximately 450 nanometers to approximately 490 nanometers). Additionally, or alternatively, the pixel sensor 204b may include a color filter that limits the pixel sensor 204b to absorbing and accumulating photons of incident light corresponding to green visible light (e.g., electromagnetic waves having a wavelength in a range of approximately 490 nanometers to approximately 570 nanometers). Additionally, or alternatively, the pixel sensor 204c may include a color filter that limits the pixel sensor 204c to absorbing and accumulating photons of incident light corresponding to red visible light (e.g., electromagnetic waves having a wavelength in a range of approximately 620 nanometers to approximately 750 nanometers). Additionally, or alternatively, the pixel sensor 204d may include a filter that limits the pixel sensor 204d to absorbing and accumulating photons of incident light corresponding to NIR light (e.g., electromagnetic waves having a wavelength in a range of approximately 700 nanometers to approximately 2500 nanometers). Photodiodes for each pixel sensor 204a-204d of the pixel sensor array 202 may generate a charge representing the intensity or brightness of the incident light (e.g., a greater amount of charge may correspond to a greater intensity or brightness, and a lower amount of charge may correspond to a lower intensity or brightness).

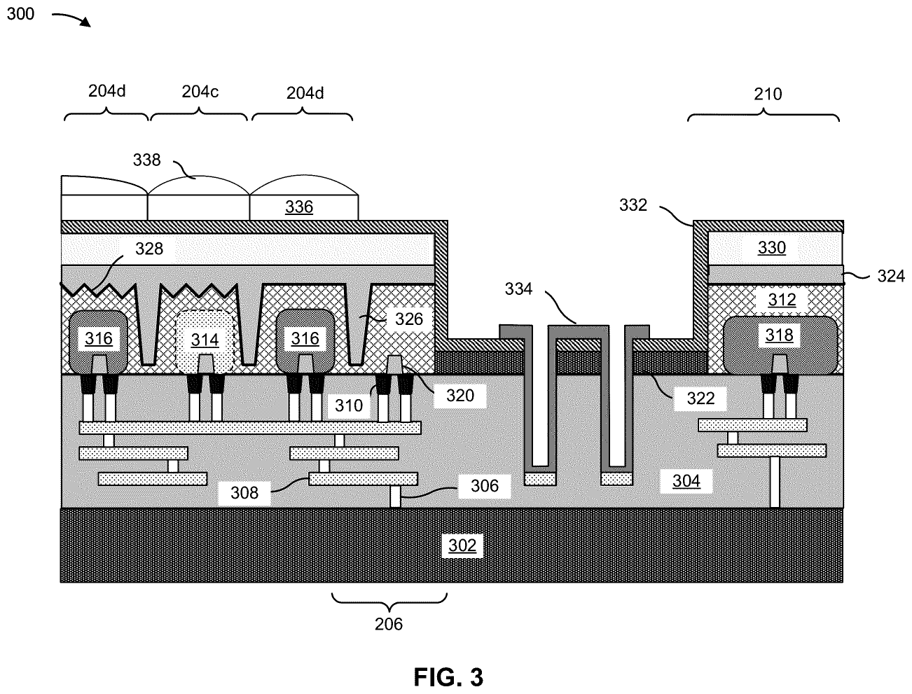

As further shown in FIG. 2, the optoelectronic device 200 includes a seal ring structure 206 that that surrounds the pixel sensor array 202 and a peripheral region 208 that includes one or more LED devices 210 (e.g., NIR LED devices). The seal ring structure 206 may provide for a physical barrier that substantially eliminates moisture and/or cracking from penetrating the optoelectronic device 200. Furthermore, and as described in greater detail in connection with FIG. 3 and elsewhere herein, the seal ring structure 206 may include a combination of interconnect structures, metallization layers, and/or deep trench isolation structures that prevent a direct transmission of NIR light from the LED devices 210 to one or more photodiodes of the pixel sensors 204a-204d.

As indicated above, FIG. 2 is provided as an example. Other examples may differ from what is described with regard to FIG. 2.

FIG. 3 is a diagram of an example optoelectronic device 300 described herein. As shown in FIG. 3 (e.g., a section view), the optoelectronic device 300 may include the pixel sensors 204c and 204d, the seal ring structure 206, and the LED device 210. The optoelectronic device 300 may be configured to be deployed in various implementations, such as digital cameras, video recorders, night-vision cameras, automotive sensors and cameras, and/or other types of light-sensing implementations.

As further shown in FIG. 3, the optoelectronic device 300 may include various layers and/or structures. In some implementations, the optoelectronic device 300 may be mounted and/or fabricated on a carrier substrate (not shown) during one or more semiconductor processing operations to form the optoelectronic device 300. As shown in FIG. 3, the optoelectronic device 300 may include a buffer layer 302. The buffer layer 302 may include a dielectric material such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material. The buffer layer 302 may serve as a layer by which the optoelectronic device 300 is bonded to the carrier substrate so that back side processing may be performed on the optoelectronic device 300.

As further shown in FIG. 3, the optoelectronic device 300 may include a dielectric region 304 above and/or on the buffer layer 302. The dielectric region 304 (e.g., an intermetal dielectric region) may include one or more layers of dielectric material (e.g., a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material). Various interconnect structures 306 (e.g., vertical interconnect access structures, or vias) and metallization layers 308 may be formed in and/or in between the layers of the dielectric region 304. The metallization layers 308 may include bonding pads, conductive lines, and/or other types of conductive structures that electrically connect the various regions of the optoelectronic device 300 and/or electrically connect the various regions of the optoelectronic device 300 to one or more external devices and/or external packaging. The interconnect structures 306 and metallization layers 308 may be referred to as a BEOL metallization stack, and may include a conductive material, such as gold, copper, silver, cobalt, tungsten, a metal alloy, or a combination thereof, among other examples.

In some implementations, portions of transistor circuitry may be included in the dielectric region 304. For example, one or more source/drain regions 310 (e.g., a doped semiconductor material such as silicon (Si) or silicon germanium (SiGe)) may be included in the dielectric region 304.

The optoelectronic device 300 may further include a substrate layer 312. The substrate layer 312 may include a semiconductor material such as silicon, a III-V compound such as gallium arsenide (GaAs), a silicon on insulator (SOI) layer, and/or another type of substrate that is capable of generating a charge from photons of incident light.

Photodiodes for the pixel array 200 are included within the substrate layer 312. A photodiode 314 to sense visible light may include a region of the substrate layer 312 that is doped with a plurality of types of ions to form a p-n junction or a p-i-n junction (e.g., a junction between a p-type portion, an intrinsic (or undoped) type portion, and an n-type portion). For example, the substrate layer 312 may be doped with an n-type dopant to form a first portion (e.g., an n-type portion) of a photodiode 314 and a p-type dopant to form a second portion (e.g., a p-type portion) of the photodiode 314.

Additionally, the substrate layer 312 may include a photodiode 316 to sense NIR light and an LED 318 to emit NIR light. The photodiode 316 and the LED 318 may include a material that is a type III periodic element or a type V periodic element. Based on properties of the material (e.g., the type III periodic element or the type V periodic element), the photodiode 316 may absorb photons with higher energies, including those in the infrared region of the spectrum, to significantly enhance a quantum efficiency of the photodiode 316 relative to the photodiode 314. Examples of the material, which may be epitaxially grown within cavities in the substrate layer 312 to selectively form the photodiode 316 and/or the LED 318, include a germanium material (Ge), a silicon germanium material (SiGe), a gallium arsenide material (GaAs), and an indium phosphide material (InP).

In some implementations, the substrate layer 312 may further include portions of transistor circuitry. For example, the substrate layer 312 may include a gate structure 320. The gate structure 320, which is formed between the source/drain regions 310, may include a conductive material such as a polysilicon material, among other examples. In some implementations, the transistor formed by the source/drain regions 310 and the gate structure 320 may be associated with a photodiode (e.g., the photodiode 314, the photodiode 316) or an LED (e.g., the LED 318). Further, and in some implementations, a shallow trench isolation (STI) region 322 is above the dielectric region 304. The STI region 322 may electrically isolate the pixel sensors 204 from other regions of the optoelectronic device 300.

As shown in FIG. 3, an oxide layer 324 is located above the substrate layer 312. The oxide layer 324 may function as a passivation layer between the substrate layer 312 and the upper layers of the pixel sensors 204. In some implementations, the oxide layer 324 includes an oxide material such as a silicon oxide (SiOₓ). In some implementations, a silicon nitride (SiNₓ), a silicon carbide (SiCₓ), or a mixture thereof, such as a silicon carbon nitride (SiCN), a silicon oxynitride (SiON), or another dielectric material is used in place of the oxide layer 324 as a passivation layer.

The oxide layer 324 may fill deep trench isolation (DTI) structures 326 be included in the substrate layer 312. In particular, DTI structures 326 may be formed between each of the photodiodes 314 and 316. The DTI structures 326 may form a grid layout in which DTI structures 326 extend laterally across the pixel array 200 and intersect at various locations of the pixel array 200. The DTI structures 326 may include trenches (e.g., deep trenches) that extend downward into the substrate layer 312 adjacent to the photodiodes 314 and 316. The DTI structures 326 may provide optical isolation between the pixel sensors 204 of the pixel array 200 to reduce the amount of optical crosstalk between adjacent pixel sensors 204. In particular, DTI structures 326 may absorb, refract, and/or reflect incident light, which may reduce the amount of incident light that travels through a pixel sensor 204 into an adjacent pixel sensor 204 and is absorbed by the adjacent pixel sensor 204. In some implementations, the DTI structures 326 are included as part of the seal ring structure 206 to prevent NIR light originating from the LED 318 from entering the photodiode 314 and/or 316.

One or more HA regions 328 may be located above one or more photodiodes 314 and/or 316. Each HA region 328 may be defined by a shallow trench. A plurality of adjacent HA regions 328 may form a periodic or zig-zag structure in the substrate layer 312 and/or the photodiode 314 and/or 316. The one or more HA regions 328 may be formed in a same side of the substrate layer 312 as the DTI structures 326.

The HA region 328 may increase the absorption of incident light for a pixel sensor 204 (thereby increasing the quantum efficiency of the pixel sensor 202) by modifying or changing the orientation of the refractive interface between the photodiodes 314 and 316 and the substrate layer 312. The angled walls of the HA region 328 changes the orientation of the interface between the photodiodes 314 and 316 and the substrate layer 312 by causing the interface to be diagonal relative to the orientation of a top surface of the substrate layer 312. This change in orientation may result in a smaller angle of refraction relative to a flat surface of the top surface of the substrate layer 312 for the same angle of incidence of incident light. As a result, the HA region 328 is capable of directing wider angles of incident light toward the center of the photodiodes 314 and 316 than if no HA region 328 were included in the optoelectronic device 300.

In some implementations, a top surface of the substrate layer 312, the surfaces of the DTI structures 326, and the surfaces of the HA region 328 may be coated with an antireflective coating (ARC) layer to decrease reflection of incident light away from the photodiodes 314 and 316 to increase transmission of incident light into the substrate layer 312 and the photodiodes 314 and 316.

As further shown in FIG. 3, one or more passivation layers may be formed above and/or on the oxide layer 324. For example, a backside illumination (BSI) oxide layer 330 may be located above and/or on portions of the oxide layer 324. As another example, a buffer oxide layer 332 may be located above and/or on the BSI oxide layer 330. In some implementations, the BSI oxide layer 330 and/or the buffer oxide layer 332 include an oxide material such as a silicon oxide (SiOₓ). In some implementations, a silicon nitride (SiNₓ), a silicon carbide (SiCₓ), or a mixture thereof, such as a silicon carbon nitride (SiCN), a silicon oxynitride (SiON), or another dielectric material is used in place of the BSI oxide layer 330 and/or the buffer oxide layer 332 as a passivation layer.

A bonding pad 334 may be located above the STI region 322, and/or above and/or on the buffer oxide layer 332. The bonding pad 334 may extend through the buffer oxide layer 332, through the STI region 322, and to the dielectric region 304, and may contact one or more metallization layers 308 in the dielectric region 304. The bonding pad 334 may include a conductive material, such as gold, silver, aluminum, copper, aluminum-copper, titanium, tantalum, titanium nitride, tantalum nitride, tungsten, a metal alloy, other metals, or a combination thereof. The bonding pad 334 may provide electrical connections between the metallization layers 308 of the optoelectronic device 300 and external devices and/or external packaging.

A filter layer 336 (e.g., corresponding to portions of a color filter array or a near infrared filter array) may be included above and/or on the buffer oxide layer 332 for one or more pixel sensors 204. The filter layer 336 may include one or more visible light color filter regions configured to filter particular wavelengths or wavelength ranges of visible light (e.g., that permit particular wavelengths or wavelength ranges of visible light to pass through the filter layer 336), one or more near infrared (NIR) filter regions (e.g., NIR bandpass filter regions) configured to permit wavelengths associated with NIR light to pass through the filter layer 336 and to block other wavelengths of light, one or more NIR cut filter regions configured to block NIR light from passing through the filter layer 336, and/or other types of filter regions. In some implementations, one or more pixel sensors 204 are each configured with a filter region of the filter layer 336. In some implementations, a micro-lens layer 338 is included above and/or on the filter layer 336. The micro-lens layer 338 may include a plurality of micro-lenses. In particular, the micro-lens layer 338 may include a respective micro-lens for each of the pixel sensors 204 included in the pixel array 200.

The number and arrangement of components, structures, and/or layers shown in the optoelectronic device 300 of FIG. 3 are provided as an example. In practice, the optoelectronic device 300 may include additional components, structures, and/or layers; fewer components, structures, and/or layers; different components, structures, and/or layers; and/or differently arranged components, structures, and/or layers than those shown in FIG. 3.

As described in connection with FIGS. 2 and 3, and in an example implementation, a semiconductor device (e.g., the optoelectronic device 300) includes a layer of a semiconductor material (e.g., the substrate layer 312). The semiconductor device includes a near infrared photodiode (e.g., the photodiode 316) within the layer of the silicon material that include a first epitaxial material. The semiconductor device includes a near infrared light emitting diode (e.g., LED 318) within the layer of the silicon material that includes a second epitaxial material. The semiconductor device includes a deep trench isolation structure (e.g., the DTI structure 326) between the near infrared photodiode and the near infrared light emitting diode.

In another example implementation, a semiconductor device (e.g., the optoelectronic device 300) includes a layer of a semiconductor material (e.g., the substrate layer 312). The semiconductor device includes an array of pixel structures (e.g., the pixel sensor array 202 including the pixel sensors 204) including an array of visible light photodiodes (e.g., the photodiodes 314) within the layer of the semiconductor material and an array of near infrared photodiodes (e.g., the photodiodes 316) including a selectively grown epitaxial material and interspersed amongst the array of visible light photodiodes. The semiconductor device includes a plurality of near infrared light emitting diodes (e.g., the LED 318) including the selectively grown epitaxial material and dispersed near, and along, a perimeter (e.g., the peripheral region 208) of the semiconductor device. The semiconductor device includes a seal ring structure (e.g., the seal ring structure 206) between the plurality of near infrared light emitting diodes and the array of near infrared photodiodes.

The semiconductor device (e.g., an optoelectronic device 300) includes NIR LEDs (e.g., the LEDs 318), NIR photodiodes (e.g., the photodiodes 316), and VIS photodiodes (e.g., the photodiodes 314) combined in a single substrate (e.g., the substrate layer 312). The NIR LEDs and the NIR photodiodes are formed using a selectively grown epitaxial material. The selectively grown epitaxial material (e.g., silicon germanium (SiGe), gallium arsenide (GaAs), or another type III/V material) improves a QE performance of the NIR photodiodes relative to other NIR photodiodes that may be formed through doping a silicon material.

By combining the NIR LEDs, the NIR photodiodes, and the VIS photodiodes on the single substrate, a complexity and/or number of manufacturing operations to form the image detection system is lesser relative to the complexity and/or number of manufacturing operations to form another image detection system using discrete NIR LED devices, NIR photodiode devices, and VIS photodiode devices.

In this way, a performance (e.g., a QE) of the NIR pixel sensor device including the NIR photodiodes is improved relative to another NIR pixel sensor device including a doped, organic photodiode. Improving the performance of the NIR pixel sensor device increases a manufacturing yield, of the NIR pixel sensor device, to a particular performance threshold. Additionally, combining the NIR LEDs, the NIR photodiodes, and the VIS photodiodes on the single substrate consumes less overall device space (e.g., silicon) and/or image detection system space. By increasing the manufacturing yield and consuming less device space and/or image detection system space, an amount of resources required to support a market that consumes a volume of the image detection system including NIR LED devices, NIR pixel sensor devices, and the VIS pixel sensor devices (e.g. semiconductor manufacturing tools, labor, raw materials, and/or computing resources) is reduced.

FIGS. 4A-4N are diagrams of an example implementation 400 for forming an optoelectronic device including near infrared photodiodes and near infrared light emitting diodes. As part of the implementation 400, a series of operations may be performed by one or more of the semiconductor processing tools 102-116 and/or the wafer/die transport tool 118 described in connection with FIG. 1.

As shown in FIG. 4A, a carrier structure 402 (a glass carrier structure or a silicon carrier structure, among other examples) holds the substrate layer 312. The deposition tool 102 may deposit the substrate layer 312 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the substrate layer 312 after the deposition tool 102 deposits the substrate layer 312.

To accommodate formation of photodiodes (e.g., the photodiodes 314 and/or 316) and/or LEDs (e.g., the LED 318), substrate layer 312 may include a thickness D1 of approximately 2.25 microns to approximately 2.75 microns. However, other values and ranges for the thickness D1 are within the scope of the present disclosure.

As part of the series of operations, the STI region 322 is formed in the substrate layer 312. As an example, the deposition tool 102, the exposure tool 104, the developer tool 106, and/or the etch tool 108 may perform a combination of photolithography, etching, and deposition operations to form the STI region 322 in the substrate layer 312.

As shown in FIG. 4B, and as part of the series of operations, a masking layer 404 is formed and patterned over the substrate layer 312. For example, and as part of forming the masking layer 404, the deposition tool 102 may deposit a layer of a silicon nitride (SiN) material in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the masking layer 404 after the deposition tool 102 deposits the masking layer 404. Furthermore, as part of patterning the masking layer 404, the exposure tool 104, the developer tool 106, and/or the etch tool 108 may perform a combination of photolithography and etching, operations to form the pattern.

As further shown in FIG. 4B, cavities 406 (e.g., cavities for the photodiodes 316) and 408 (e.g., cavities for the LED 318) are formed in the substrate layer 312. To form the cavities 406 and 408, the pattern in the masking layer 404 is used. The etch tool 108 etches the substrate layer 312 based on the pattern to form the cavities 406 and 408 in the substrate layer 312. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique).

Turning to FIG. 4C, the photodiode(s) 316 and the LED 318 are formed, respectively, in the cavities 406 and 408. The deposition tool 102 may deposit the photodiode(s) 316 and the LED 318 in an epitaxy operation (e.g., a selective epitaxial growth operation), a deposition operation described in connection with FIG. 1, and/or another suitable deposition operation. In some implementations, the planarization tool 110 planarizes the photodiode(s) 316 and the LED 318 after the deposition tool 102 deposits the photodiode(s) 316 and the LED 318. Additionally, or alternatively, the planarization tool 110 may remove the masking layer 404 after the deposition tool 102 deposits the photodiode(s) 316 and the LED 318.

In some implementations, a thickness D2 of the LED 318 and/or the photodiodes 316 (e.g., a thickness of the selectively grown epitaxial material) is included in a range of approximately 1.8 microns to approximately 2.2 microns. However, other values and ranges of the thickness D2 are within the scope of the present disclosure.

As shown in FIG. 4D, and as part of the series of operations, the photodiode 314 is formed in the substrate layer 312. As an example, the deposition tool 102, the exposure tool 104, the developer tool 106, the etch tool 108, and/or the ion implantation tool 114 may perform a combination of deposition, photolithography, etching, and/or implant operations to implant ions in a defined region below the surface of the substrate to form the photodiode 314.

Additionally, and as shown in FIG. 4D, the gate structures 320 may be formed in the substrate layer 312. As an example, the deposition tool 102, the exposure tool 104, the developer tool 106, the etch tool 108, and/or the ion implantation tool 114 may perform a combination of deposition, photolithography, etching, and/or implant operations to form the gate structures 320.

As shown in FIG. 4E, the dielectric region 304 is formed above and/or on the substrate layer 312. As part of forming the dielectric region 304, and as an example, the deposition tool 102 may deposit one or more dielectric layers of the dielectric region 304 using a CVD operation, a PVD operation, an ALD operation, another deposition operation described above in connection with FIG. 1, and/or another suitable deposition operation. In some implementations, the planarization tool 110 planarizes the one or more of the dielectric layers after the deposition tool 102 deposits the dielectric layers.

Additionally, or alternatively and as part of forming the dielectric region 304, the deposition tool 102, the exposure tool 104, the developer tool 106, and/or the etch tool 108 may perform a combination of deposition, photolithography, and/or etching operations to form the interconnect structures 306. The deposition tool 102 or the plating tool 112 may further form one or more of the metallization layers 308. To form one or more of the metallization layers 308, the deposition tool 102 and/or the plating tool 112 may deposit one or more of the metallization layers 308 in a CVD operation, a PVD operation, an ALD operation, an electroplating operation, another deposition operation described above in connection with FIG. 1, and/or another suitable deposition operation. In some implementations, the planarization tool 110 planarizes one or more of the metallization layers 308 after deposition.

As shown in FIG. 4F, and as part of the series of operations, the bonding/debonding tool 116 may remove the carrier structure 402 (e.g., separate the carrier structure 402 and the substrate layer 312). Furthermore, and as FIG. 4F, the buffer layer 302 is formed over and/or on the dielectric region 304. The deposition tool 102 may deposit the buffer layer 302 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the buffer layer 302 after the deposition tool 102 deposits the buffer layer 302.

Turning to FIG. 4G, and as part of the series of operations, the etch tool 108 may form cavities 408 (e.g., cavities for the DTI structures 326) and cavities 410 (e.g., cavities for the HA regions 328). In some implementations, a pattern in a photoresist layer is used to etch the substrate layer 312 to form the cavities 408 and 410. In these implementations, the deposition tool 102 forms the photoresist layer on the substrate layer 312. The exposure tool 104 exposes the photoresist layer to a radiation source to pattern the photoresist layer. The developer tool 106 develops and removes portions of the photoresist layer to expose the pattern. The etch tool 108 etches the substrate layer 312 based on the pattern to form the cavities 408 and 410 in the substrate layer 312. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the substrate layer 312 based on a pattern.

As shown in FIG. 4H, the oxide layer 324 is formed over and/or on the substrate layer 312. The deposition tool 102 may deposit the oxide layer 324 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the oxide layer 324 after the deposition tool 102 deposits the oxide layer 324. As part of forming the oxide layer 324, the cavities 408 and 410 may be filled with oxide to form the DTI structures 326 and the HA regions 328. In some implementations, the deposition tool 102 deposits an anti-reflective (ARC) layer prior to depositing the oxide layer 324.

As shown in FIG. 4I, the BSI oxide layer 330 is formed over and/or on the oxide layer 324. The deposition tool 102 may deposit the BSI oxide layer 330 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the BSI oxide layer 330 after the deposition tool 102 deposits the BSI oxide layer 330.

Turning to FIG. 4J, and as part of the series of operations, a cavity 412 is formed through the BSI oxide layer 330, the oxide layer 324, and the substrate layer 312 to the STI region 322. In some implementations, a pattern in a photoresist layer is used to etch the BSI oxide layer 330, the oxide layer 324, and the substrate layer 312 to form the cavity 412. In these implementations, the deposition tool 102 forms the photoresist layer on the substrate layer 312. The exposure tool 104 exposes the photoresist layer to a radiation source to pattern the photoresist layer. The developer tool 106 develops and removes portions of the photoresist layer to expose the pattern. The etch tool 108 etches the cavity 412 based on the pattern to form the cavity 412 in the BSI oxide layer 330, the oxide layer 324, and the substrate layer 312. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the BSI oxide layer 330, the oxide layer 324, and the substrate layer 312 based on a pattern.

As shown in FIG. 4K, the buffer oxide layer 332 is formed over and/or on the BSI oxide layer 330. The deposition tool 102 may deposit the buffer oxide layer 332 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the buffer oxide layer 332 after the deposition tool 102 deposits the buffer oxide layer 332.

As shown FIG. 4L, cavities 414 are formed through buffer oxide layer 332, through the STI region 322, and into the dielectric region 304. In some implementations, the cavities 414 expose portions of the metallization layers 308. In some implementations, a pattern in a photoresist layer is used to etch the buffer oxide layer 332, the STI region 322, and the dielectric region 304 to form the cavity 414. In these implementations, the deposition tool 102 forms the photoresist layer on the buffer oxide layer 332. The exposure tool 104 exposes the photoresist layer to a radiation source to pattern the photoresist layer. The developer tool 106 develops and removes portions of the photoresist layer to expose the pattern. The etch tool 108 etches the buffer oxide layer 332, the STI region 322, and the dielectric region 304 based on the pattern to form the cavities 414 through buffer oxide layer 332, through the STI region 322, and into the dielectric region 304. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the buffer oxide layer 332, the STI region 322, and the dielectric region 304 based on a pattern.

As part of the series of operations and as shown in FIG. 4M, the bonding pad 334 is formed in the cavities 414. In some implementations, portions of the bonding pad 334 are formed on portions of the metallization layers 308. As an example, the deposition tool 102, the exposure tool 104, the developer tool 106, and/or the etch tool 108 may perform a combination of deposition, photolithography, and/or etching operations to form the bonding pad 334.

Turning to FIG. 4N, and as part of the series of operations, the filter layer 336 and the micro-lens layer 338 are formed over and/or on the buffer oxide layer 332. As an example, the deposition tool 102, the exposure tool 104, the developer tool 106, and/or the etch tool 108 may perform a combination of deposition, photolithography, and/or etching operations to form the filter layer 336 and the micro-lens layer 338.

As indicated above, FIGS. 4A-4N are provided as an example. Other examples may differ from what is described with regard to FIGS. 4A-4N.

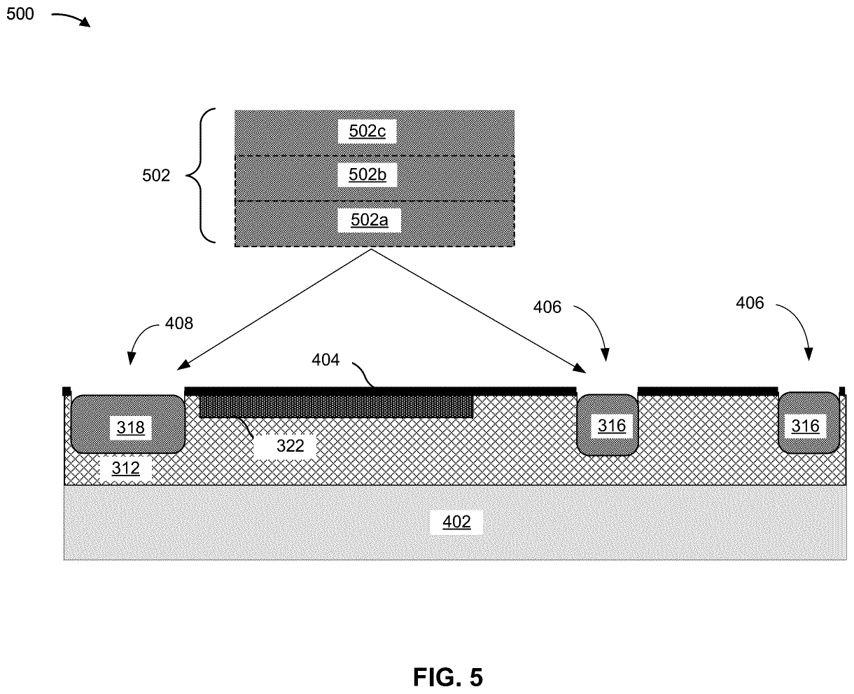

FIG. 5 is a diagram of an example implementation 500 described herein. The example implementation 500 includes an example layer stack of epitaxial materials 502 that may be selectively grown to form the photodiode 316 and/or the LED 318.

As shown in FIG. 5, an n-type layer of silicon-germanium material 502a may be formed in a cavity. As further shown in FIG. 5, an intrinsic layer of silicon-germanium material 502b may be formed over the n-type layer of silicon germanium material 502a. As further shown in FIG. 5, a p-type layer of silicon-germanium material 502c may be formed over the intrinsic layer of silicon germanium material 502b. The deposition tool 102 may deposit the layer stack of epitaxial materials 502 using the epitaxy operations described in connection with FIG. 1, and/or another suitable deposition operation.

In some implementations, the deposition tool 102 forms the layer stack of epitaxial materials 502 in only a single cavity (e.g., the cavity 406 or the cavity 408). In such a case, an epitaxial material in a first cavity (e.g., the cavity 408) may be a different selectively grown epitaxial material than a selectively grown epitaxial material in a second cavity, and separate masking and patterning operations may be implemented to form the different selectively grown epitaxial materials.

In some implementations, the deposition tool 102 forms the layer stack of epitaxial materials 502 in multiple cavities simultaneously (e.g., the cavity 406 and the cavity 408). In such a case, a single masking and patterning operation (e.g., as described in connection with FIG. 4B) may be implemented to form a same selectively grown epitaxial material.

As indicated above, FIG. 5 is provided as an example. Other examples may differ from what is described with regard to FIG. 5.

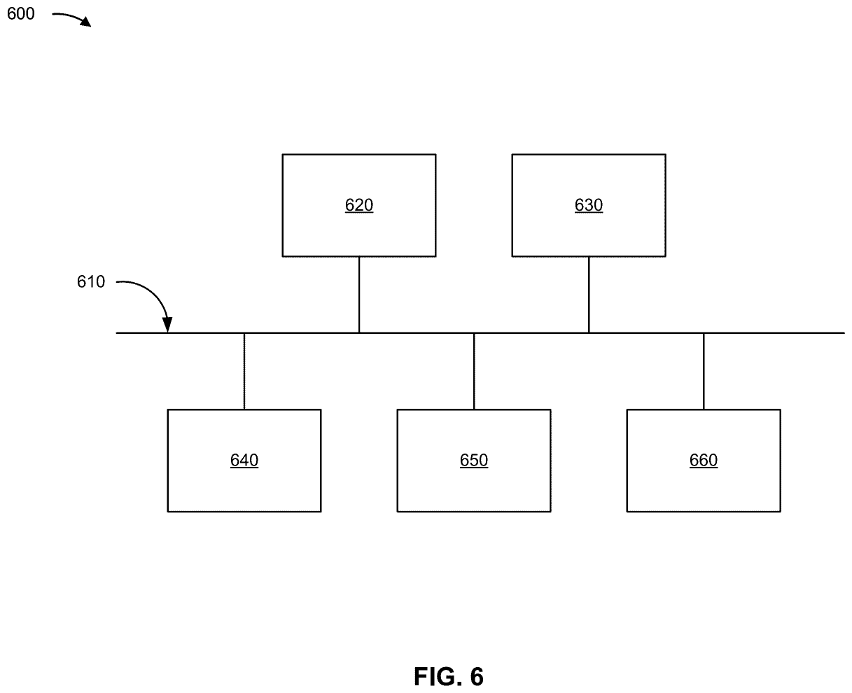

FIG. 6 is a diagram of example components of a device 600 associated with forming an optoelectronic device including near infrared photodiodes and near infrared light emitting diodes. The device 600 may correspond to one or more of the semiconductor processing tools 102-116 and/or the wafer/die transport tool 118. In some implementations, one or more of the semiconductor processing tools 102-116 and/or the wafer/die transport tool 118 may include one or more devices 600 and/or one or more components of the device 600. As shown in FIG. 6, the device 600 may include a bus 610, a processor 620, a memory 630, an input component 640, an output component 650, and/or a communication component 660.

The bus 610 may include one or more components that enable wired and/or wireless communication among the components of the device 600. The bus 610 may couple together two or more components of FIG. 6, such as via operative coupling, communicative coupling, electronic coupling, and/or electric coupling. For example, the bus 610 may include an electrical connection (e.g., a wire, a trace, and/or a lead) and/or a wireless bus. The processor 620 may include a central processing unit, a graphics processing unit, a microprocessor, a controller, a microcontroller, a digital signal processor, a field-programmable gate array, an application-specific integrated circuit, and/or another type of processing component. The processor 620 may be implemented in hardware, firmware, or a combination of hardware and software. In some implementations, the processor 620 may include one or more processors capable of being programmed to perform one or more operations or processes described elsewhere herein.

The memory 630 may include volatile and/or nonvolatile memory. For example, the memory 630 may include random access memory (RAM), read only memory (ROM), a hard disk drive, and/or another type of memory (e.g., a flash memory, a magnetic memory, and/or an optical memory). The memory 630 may include internal memory (e.g., RAM, ROM, or a hard disk drive) and/or removable memory (e.g., removable via a universal serial bus connection). The memory 630 may be a non-transitory computer-readable medium. The memory 630 may store information, one or more instructions, and/or software (e.g., one or more software applications) related to the operation of the device 600. In some implementations, the memory 630 may include one or more memories that are coupled (e.g., communicatively coupled) to one or more processors (e.g., processor 620), such as via the bus 610. Communicative coupling between a processor 620 and a memory 630 may enable the processor 620 to read and/or process information stored in the memory 630 and/or to store information in the memory 630.

The input component 640 may enable the device 600 to receive input, such as user input and/or sensed input. For example, the input component 640 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 650 may enable the device 600 to provide output, such as via a display, a speaker, and/or a light-emitting diode. The communication component 660 may enable the device 600 to communicate with other devices via a wired connection and/or a wireless connection. For example, the communication component 660 may include a receiver, a transmitter, a transceiver, a modem, a network interface card, and/or an antenna.

The device 600 may perform one or more operations or processes described herein. For example, a non-transitory computer-readable medium (e.g., memory 630) may store a set of instructions (e.g., one or more instructions or code) for execution by the processor 620. The processor 620 may execute the set of instructions to perform one or more operations or processes described herein. In some implementations, execution of the set of instructions, by one or more processors 620, causes the one or more processors 620 and/or the device 600 to perform one or more operations or processes described herein. In some implementations, hardwired circuitry may be used instead of or in combination with the instructions to perform one or more operations or processes described herein. Additionally, or alternatively, the processor 620 may be configured to perform one or more operations or processes described herein. Thus, implementations described herein are not limited to any specific combination of hardware circuitry and software.

The number and arrangement of components shown in FIG. 6 are provided as an example. The device 600 may include additional components, fewer components, different components, or differently arranged components than those shown in FIG. 6. Additionally, or alternatively, a set of components (e.g., one or more components) of the device 600 may perform one or more functions described as being performed by another set of components of the device 600.

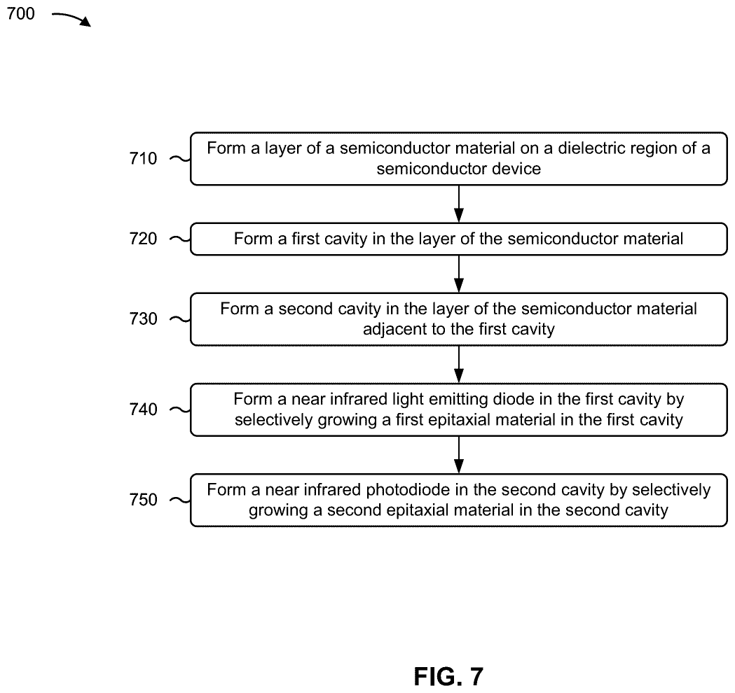

FIG. 7 is a flowchart of an example process 700 associated with forming an optoelectronic device including near infrared photodiodes and near infrared light emitting diodes. In some implementations, one or more process blocks of FIG. 7 are performed by one or more semiconductor processing tools (e.g., one or more of the semiconductor processing tools 102-116 and/or the wafer/die transport tool 118). Additionally, or alternatively, one or more process blocks of FIG. 7 may be performed by one or more components of device 600, such as processor 620, memory 630, input component 640, output component 650, and/or communication component 660.

As shown in FIG. 7, process 700 may include forming a layer of a semiconductor material on a dielectric region of a semiconductor device (block 710). For example, one or more of the semiconductor processing tools 102-116 may form a layer of a semiconductor material (e.g., the substrate layer 312) on a dielectric region (e.g., the dielectric region 304) of a semiconductor device (e.g., the optoelectronic device 300), as described herein.

As further shown in FIG. 7, process 700 may include forming a first cavity in the layer of the semiconductor material (block 720). For example, one or more of the semiconductor processing tools 102-116 may form a first cavity (e.g., the cavity 406) in the layer of the semiconductor material, as described herein.

As further shown in FIG. 7, process 700 may include forming a second cavity in the layer of the semiconductor material adjacent to the first cavity (block 730). For example, one or more of the semiconductor processing tools 102-116 may form a second cavity (e.g., the cavity 408) in the layer of the semiconductor material adjacent to the first cavity, as described herein.

As further shown in FIG. 7, process 700 may include forming a near infrared light emitting diode in the first cavity by selectively growing a first epitaxial material in the first cavity (block 740). For example, one or more of the semiconductor processing tools 102-116 may form a near infrared light emitting diode (e.g., the LED 318) in the first cavity by selectively growing a first epitaxial material in the first cavity, as described herein.

As further shown in FIG. 7, process 700 may include forming a near infrared photodiode in the second cavity by selectively growing a second epitaxial material in the second cavity (block 750). For example, one or more of the semiconductor processing tools 102-116 may form a near infrared photodiode (e.g., the photodiode 316) in the second cavity by selectively growing a second epitaxial material in the second cavity, as described herein.

Process 700 may include additional implementations, such as any single implementation or any combination of implementations described below and/or in connection with one or more other processes described elsewhere herein.

In a first implementation, forming the near infrared photodiode in the first cavity by selectively growing the first epitaxial material in the first cavity comprises selectively growing an n-type layer of silicon-germanium material in the first cavity, selectively growing an intrinsic layer of silicon-germanium material over the n-type layer of silicon germanium material in the first cavity, and selectively growing a p-type layer of silicon-germanium material over the intrinsic layer of silicon germanium material in the first cavity.

In a second implementation, alone or in combination with the first implementation, forming the near infrared light emitting diode in the second cavity by selectively growing the second epitaxial material in the second cavity comprises selectively growing an n-type layer of silicon-germanium material in the second cavity, selectively growing an intrinsic layer of silicon-germanium material over the n-type layer of silicon germanium material in the second cavity, and selectively growing a p-type layer of silicon-germanium material over the intrinsic layer of silicon germanium material in the second cavity.

In a third implementation, alone or in combination with one or more of the first and second implementations, process 700 includes joining the layer of the semiconductor material and a layer of a dielectric material (e.g., the dielectric region 304) after forming the near infrared photodiode and the near infrared light emitting diode.

In a fourth implementation, alone or in combination with one or more of the first through third implementations, process 700 includes forming a lens over the near infrared photodiode.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

Some implementations described herein include an optoelectronic device for a low-lighting application and techniques to form the optoelectronic device. The optoelectronic device includes NIR LEDs, NIR photodiodes, and VIS photodiodes combined in a single substrate. The NIR LEDs and NIR photodiodes are formed using a selectively grown epitaxial material. The selectively grown epitaxial material (e.g., silicon germanium (SiGe), gallium arsenide (GaAs), or another type III/V material) improves a QE performance of the NIR photodiode relative to another photodiode that is formed through doping a silicon material.

By combining the NIR LEDs, the NIR photodiodes, and the VIS photodiodes on the single substrate, a complexity and/or number of manufacturing operations to form the image detection system is lesser relative to the complexity and/or number of manufacturing operations to form another image detection system using discrete NIR LED devices, NIR photodiode devices, and VIS photodiode devices.

In this way, a performance (e.g., a QE) of an NIR pixel sensor device including the NIR photodiode is improved relative to another NIR pixel sensor device including a doped, organic photodiode. Improving the performance of the NIR pixel sensor device increases a manufacturing yield, of the NIR pixel sensor device, to a particular performance threshold. Additionally, combining the NIR LEDs, the NIR photodiodes, and the VIS photodiodes on the single substrate consumes less overall device space (e.g., silicon) and/or image detection system space. By increasing the manufacturing yield and consuming less device space and/or image detection system space, an amount of resources required to support a market that consumes a volume of the image detection system including the NIR LEDs, the NIR photodiodes, and the VIS photodiodes (e.g. semiconductor manufacturing tools, labor, raw materials, and/or computing resources) is reduced.

As described in greater detail above, some implementations described herein provide a semiconductor device. The semiconductor device includes a layer of a silicon material. The semiconductor device includes a near infrared photodiode within the layer of the silicon material that include a first epitaxial material. The semiconductor device includes a near infrared light emitting diode within the layer of the silicon material that includes a second epitaxial material. The semiconductor device includes a deep trench isolation structure between the near infrared photodiode and the near infrared light emitting diode.

As described in greater detail above, some implementations described herein provide a semiconductor device. The semiconductor device includes a layer of a semiconductor material. The semiconductor device includes an array of pixel structures including an array of visible light photodiodes within the layer of the semiconductor material and an array of near infrared photodiodes including a selectively grown epitaxial material and interspersed amongst the array of visible light photodiodes. The semiconductor device includes a plurality of near infrared light emitting diodes including the selectively grown epitaxial material and dispersed near, and along, a perimeter of the semiconductor device. The semiconductor device includes a seal ring structure between the plurality of near infrared light emitting diodes and the array of near infrared photodiodes.

As described in greater detail above, some implementations described herein provide a method. The method includes forming a layer of a semiconductor material on a dielectric region of a semiconductor device. The method includes forming a first cavity in the layer of the semiconductor material. The method includes forming a second cavity in the layer of the semiconductor material adjacent to the first cavity. The method includes forming a near infrared light emitting diode in the first cavity by selectively growing a first epitaxial material in the first cavity. The method includes forming a near infrared photodiode in the second cavity by selectively growing a second epitaxial material in the second cavity.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a layer of a silicon material;
a near infrared photodiode within the layer of the silicon material and comprising:
a first epitaxial material;
a near infrared light emitting diode within the layer of the silicon material and comprising:
a second epitaxial material; and
a deep trench isolation structure between the near infrared photodiode and the near infrared light emitting diode.

2. The semiconductor device of claim 1, wherein the first epitaxial material and the second epitaxial material are a same selectively grown epitaxial material.

3. The semiconductor device of claim 1, wherein the first epitaxial material and the second epitaxial material are different selectively grown epitaxial materials.

4. The semiconductor device of claim 1, wherein the first epitaxial material or the second epitaxial material comprises:
a type III periodic element, or
a type V periodic element.

5. The semiconductor device of claim 1, wherein the first epitaxial material or the second epitaxial material comprises:
a germanium material;
a silicon germanium material;
a gallium arsenide material; or
an indium phosphide material.

6. The semiconductor device of claim 1, further comprising:
a seal ring structure between the near infrared photodiode and the near infrared light emitting diode.

7. The semiconductor device of claim 1, further comprising:
a visible light photodiode adjacent to the near infrared photodiode.

8. A semiconductor device, comprising:
a layer of a semiconductor material;
an array of pixel structures comprising:
an array of visible light photodiodes within the layer of the semiconductor material; and
an array of near infrared photodiodes comprising a selectively grown epitaxial material and interspersed amongst the array of visible light photodiodes;
a plurality of near infrared light emitting diodes comprising the selectively grown epitaxial material and dispersed near, and along, a perimeter of the semiconductor device; and
a seal ring structure between the plurality of near infrared light emitting diodes and the array of near infrared photodiodes.

9. The semiconductor device of claim 8, wherein the array of visible light photodiodes within the layer of the semiconductor material comprises:
the selectively grown epitaxial material.

10. The semiconductor device of claim 8, wherein the layer of the semiconductor material comprises a silicon material, and wherein the array of visible light photodiodes within the layer of the silicon material comprises:
the silicon material doped with a plurality of ions to form a p-n junction or a p-i-n junction.

11. The semiconductor device of claim 8, further comprising:
at least one deep trench isolation structure between the plurality of near infrared light emitting diodes and the array of near infrared light emitting diodes.

12. The semiconductor device of claim 8, further comprising:
a color filter array over the array of visible light photodiodes.

13. The semiconductor device of claim 8, further comprising:
transistor circuitry within the layer of silicon material.

14. The semiconductor device of claim 8, further comprising:
a near infrared filter array over the array of near infrared photodiodes.

15. The semiconductor device of claim 8, further comprising:
one or more dielectric layers below the layer of semiconductor material; and
one or more conductive structures interspersed with the one or more dielectric layers.

16. A method, comprising:
forming a layer of a semiconductor material on a dielectric region of a semiconductor device;
forming a first cavity in the layer of the semiconductor material;
forming a second cavity in the layer of the semiconductor material adjacent to the first cavity;
forming a near infrared light emitting diode in the first cavity by selectively growing a first epitaxial material in the first cavity; and
forming a near infrared photodiode in the second cavity by selectively growing a second epitaxial material in the second cavity.

17. The method of claim 16, wherein forming the near infrared photodiode in the first cavity by selectively growing the first epitaxial material in the first cavity comprises:
selectively growing an n-type layer of silicon-germanium material in the first cavity;
selectively growing an intrinsic layer of silicon-germanium material over the n-type layer of silicon germanium material in the first cavity; and
selectively growing a p-type layer of silicon-germanium material over the intrinsic layer of silicon germanium material in the first cavity.

18. The method of claim 16, wherein forming the near infrared light emitting diode in the second cavity by selectively growing the second epitaxial material in the second cavity comprises:
selectively growing an n-type layer of silicon-germanium material in the second cavity;
selectively growing an intrinsic layer of silicon-germanium material over the n-type layer of silicon germanium material in the second cavity; and
selectively growing a p-type layer of silicon-germanium material over the intrinsic layer of silicon germanium material in the second cavity.

19. The method of claim 16, further comprising:
joining the layer of the semiconductor material and a layer of a dielectric material after forming the near infrared photodiode and the near infrared light emitting diode.

20. The method of claim 16, further comprising:
forming a lens over the near infrared photodiode.
